(19) United States
(12) Patent Application Publication
(10) Pub. No.: US 2024/0145206 A1
(43) Pub. Date: May 2, 2024

(54) TEMPERATURE CONTROLLED ELECTRODE TO LIMIT DEPOSITION RATES AND DISTORTION

(71) Applicant: Applied Materials, Inc., Santa Clara, CA (US)

(72) Inventor: James P. Buonodono, Amesbury, MA (US)

(21) Appl. No.: 17/975,016

(22) Filed: Oct. 27, 2022

(51) Int. Cl. H01J 37/08; H01J 37/16

(52) U.S. Cl. CPC H01J 37/08; H01J 37/16; H01J 2237/002

(57) ABSTRACT

An apparatus for limiting the deposition and thermal distortion of an electrode is disclosed. The apparatus includes a fluid source in communication with a cooling channel that is embedded in the electrode. By circulating fluid through the cooling channel, a more uniform temperature may be maintained, limiting thermal distortion. Further, the cooler temperature of the electrode may also limit the rate of deposition. The cooling channel may be embedded using an additive manufacturing process.

### FIELD

Embodiments relate to an apparatus for limiting the thermal distortion of electrodes proximate an ion source, and more particularly, an electrode having an embedded cooling channel.

### BACKGROUND

Ions are used in a plurality of semiconductor processes, such as implantation, amorphization, deposition and etching processes. These ions may be created within an ion source chamber and extracted through an extraction aperture in the ion source chamber.

The ions may be attracted through the extraction aperture by an optics system disposed outside and proximate the ion source chamber. Typical optic elements for an ion source include an extraction electrode, which may be the wall of the ion source chamber that includes the extraction aperture. Other optic elements include a suppression electrode and a ground electrode. The suppression electrode may be electrically biased to attract the ions created within the ion source chamber. For example, the suppression electrode may be negatively biased to attract positive ions from within the ion source chamber. In certain embodiments, there could be up to five electrodes with the addition of a focusing lens and an additional ground electrode.

The electrodes may each be a single electrically conductive component with an aperture disposed therein. Alternatively, each electrode may be comprised of two components that are spaced apart so as to create an aperture between the two components. In both embodiments, the ion beam passes through the aperture in each electrode. The portion of the electrode disposed proximate the aperture may be referred to as the optical edge. The portion of the electrode furthest from the aperture may be referred to as the distal edge.

It is not uncommon for some portion of the ion beam extracted from the ion source chamber to strike the extraction electrode, suppression electrode and the ground electrode, causing each electrode to heat up along the optical edge. However, not all portions of these electrodes are equally impacted by the extracted ions. Consequently, these electrodes may be heated unevenly by these extracted ions.

In certain embodiments, the uneven heating of the electrodes may be problematic. This problem may be exacerbated as the length of the electrodes increases. Therefore, it would be beneficial if there were an apparatus to limit the thermal distortion caused by this uneven heating.

### SUMMARY

An apparatus for limiting the deposition and thermal distortion of an electrode is disclosed. The apparatus includes a fluid source in communication with a cooling channel that is embedded in the electrode. By circulating fluid through the cooling channel, a more uniform temperature may be maintained, limiting thermal distortion. Further, the cooler temperature of the electrode may also limit the rate of deposition. The cooling channel may be embedded using an additive manufacturing process.

According to one embodiment, apparatus for controlling thermal distortion of an electrode is disclosed. The apparatus comprises an ion source having a plurality of chamber walls defining an ion source chamber and having an extraction aperture; and an electrode disposed outside the ion source chamber and having an aperture aligned with the extraction aperture, wherein the electrode has an embedded cooling channel. In some embodiments, the apparatus comprises a fluid source in communication with the embedded cooling channel to allow a flow of fluid through the electrode. In some embodiments, the fluid source comprises a chiller. In some embodiments, the fluid source comprises a heater. In certain embodiments, the embedded cooling channel is lined with a thermally conductive material. In some embodiments, the thermally conductive material is copper. In some embodiments, the electrode comprises a suppression electrode. In some embodiments, the electrode comprises a ground electrode.

According to another embodiment, an apparatus for controlling thermal distortion and/or deposition of an electrode is disclosed. The apparatus comprises an ion source having a plurality of chamber walls defining an ion source chamber and having an extraction aperture; an electrode disposed outside the ion source chamber and having an aperture aligned with the extraction aperture, wherein the electrode has an embedded cooling channel; a fluid source in communication with the embedded cooling channel; and a controller in communication with the fluid source to control a flow rate and/or temperature of a fluid flowing through the embedded cooling channel. In some embodiments, the controller maintains the electrode within a predetermined temperature range to control thermal distortion. In some embodiments, the apparatus comprises a thermal sensor, wherein the controller uses information from the electrode to maintain the predetermined temperature range. In certain embodiments, the thermal sensor is disposed on the electrode. In certain embodiments, the thermal sensor is not in direct contact with the electrode. In some embodiments, the fluid source comprises a chiller. In some embodiments, the fluid source comprises a heater. In some embodiments, the controller controls a temperature of a fluid flowing through the embedded cooling channel based on a species being ionized in the ion source to control deposition on the electrode.

According to another embodiment, an apparatus for controlling thermal distortion of an extraction electrode is disclosed. The apparatus comprises an ion source having a plurality of chamber walls and an extraction electrode defining an ion source chamber, wherein the extraction electrode has an extraction aperture; and an electrode disposed outside the ion source chamber and having an aperture aligned with the extraction aperture, wherein the extraction electrode has an embedded cooling channel. In some embodiments, a fluid source is in communication with the embedded cooling channel to allow a flow of fluid through the extraction electrode. In some embodiments, the fluid source comprises a chiller or a heater. In some embodiments, the embedded cooling channel is lined with a thermally conductive material.

### BRIEF DESCRIPTION OF THE FIGURES

For a better understanding of the present disclosure, reference is made to the accompanying drawings, which are incorporated herein by reference and in which:

FIG. 1 shows an apparatus for controlling thermal distortion according to one embodiment;

FIG. 2A shows the suppression electrode prior to extraction and FIG. 2B shows the suppression electrode after being impacted by the extracted ion beam;

FIG. 3 shows a cross-sectional view of the electrode with the embedded channel;

FIG. 4 shows a perspective view of the electrode shown in FIGS. 3; and

FIG. 5 shows the control system for controlling the thermal distortion according to one embodiment.

### DETAILED DESCRIPTION

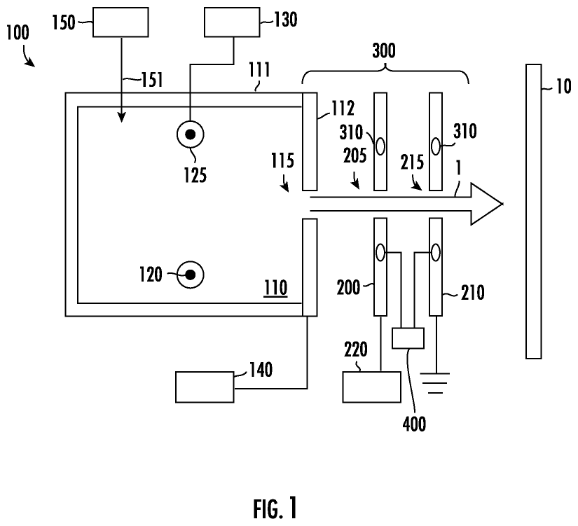

FIG. 1 shows an embodiment of an apparatus that may be used to control thermal distortion of the extraction electrode 112, the suppression electrode 200 or the ground electrode 210. In this embodiment, an RF ion source 100 is illustrated. The RF ion source 100 comprises a plurality of chamber walls 111 defining an ion source chamber 110. An RF antenna 120 may be disposed within the ion source chamber 110. The RF antenna 120 may comprise an electrically conductive material, such as copper. The RF antenna 120 may be encased in a hollow tube 125, which may be made of a dielectric material, such as quartz. An RF power supply 130 is in electrical communication with the RF antenna 120. The RF power supply 130 may supply an RF voltage to the RF antenna 120. The power supplied by the RF power supply 130 may be between 0.5 and 60 kW and may be any suitable frequency, such as between 5 and 15 MHz. Further, the power supplied by the RF power supply 130 may be pulsed.

While the figures show the RF antenna 120 encased in a hollow tube 125 within the ion source chamber 110, other embodiments are also possible. For example, one of the chamber walls 111 may be made of a dielectric material and the RF antenna 120 may be disposed outside the ion source chamber 110, proximate the dielectric wall. In yet other embodiments, the plasma is generated in a different manner, such as by a Bernas ion source or an indirectly heated cathode (IHC). The manner in which the plasma is generated is not limited by this disclosure.

In certain embodiments, the chamber walls 111 may be electrically conductive, and may be constructed of metal. In certain embodiments, these chamber walls 111 may be electrically biased. In certain embodiments, the chamber walls 111 may be grounded. In other embodiments, the chamber walls 111 may be biased at a voltage by bias power supply 140. In certain embodiments, the bias voltage may be a constant (DC) voltage. In other embodiments, the bias voltage may be pulsed. The bias voltage applied to the chamber walls 111 establishes the potential of the plasma within the ion source chamber 110. The difference between the electrical potential of the plasma and the electrical potential of the suppression electrode 200 may determine the energy that the extracted ions possess.

One chamber wall, referred to as the extraction electrode 112, includes an extraction aperture 115. The extraction aperture 115 may be an opening through which the ions generated in the ion source chamber 110 are extracted and directed toward a workpiece 10. The extraction aperture 115 may be any suitable shape. In certain embodiments, the extraction aperture 115 may be oval or rectangular shaped, having one dimension, referred to as the length, which may be much larger than the second dimension, referred to as the height. In certain embodiments, the length of the extraction aperture 115 may be as large as two meters or more. In certain embodiments, only the extraction electrode 112 is electrically conductive and in communication with the bias power supply 140. The remaining chamber walls 111 may be made of a dielectric material. In other embodiments, the extraction electrode 112 and all of the chamber walls 111 may be electrically conductive. The bias power supply 140 may bias the extraction electrode 112 at a voltage of between 1 kV and 5 kV, although other voltages are also within the scope of the disclosure.

Disposed outside and proximate the extraction aperture 115 is a suppression electrode 200. The suppression electrode 200 may be a single electrically conductive component with a suppression aperture 205 disposed therein. Alternatively, the suppression electrode 200 may be comprised of two electrically conductive components that are spaced apart so as to create the suppression aperture 205 between the two components. The suppression electrode 200 may be a metal, such as titanium. The suppression electrode 200 may be electrically biased using a suppression power supply 220. The suppression electrode 200 may be biased so as to be more negative than the extraction electrode 112. In certain embodiments, the suppression electrode 200 is negatively biased by the suppression power supply 220, such as at a voltage of between −3 kV and −15 kV, although other voltages are also within the scope of the disclosure.

Disposed proximate the suppression electrode 200 may be a ground electrode 210. Like the suppression electrode 200, the ground electrode 210 may be a single electrically conductive component with a ground aperture 215 disposed therein, or may be comprised of two components that are spaced apart so as to create the ground aperture 215 between the two components. The ground electrode 210 may be electrically connected to ground. Of course, in other embodiments, the ground electrode 210 may be biased using a separate power supply. The extraction aperture 115, the suppression aperture 205 and the ground aperture 215 are all aligned. The ground electrode 210 is positioned such that the suppression electrode 200 is located between the extraction electrode 112 and the ground electrode 210.

The workpiece 10 is located downstream from the ground electrode 210. In certain embodiments, the workpiece 10 is located immediately following the ground electrode 210. In other embodiments, additional components, such as mass analyzers, collimating magnets, acceleration and deceleration stages, may be disposed between the ground electrode 210 and the workpiece 10.

In operation, feed gas from a gas storage container 150 is introduced to the ion source chamber 110 through a gas inlet 151. The RF antenna 120 is energized by the RF power supply 130. This energy excites the feed gas, causing the creation of a plasma. Ions in that plasma are typically positively charged. Because the suppression electrode 200 is more negatively biased than the extraction electrode 112, the ions exit through the extraction aperture 115 in the form of an ion beam 1. The ion beam 1 passes through the extraction aperture 115, the suppression aperture 205 and the ground aperture 215 and travels toward the workpiece 10.

The portion of the suppression electrode 200 disposed proximate the suppression aperture 205 in the height dimension may be referred to as the optical edge. The portion of the suppression electrode 200 furthest from the suppression aperture 205 in the height dimension may be referred to as the distal edge.

Similarly, the portion of the ground electrode 210 disposed proximate the ground aperture 215 in the height dimension may be referred to as the optical edge. The portion of the ground electrode 210 furthest from the ground aperture 215 in the height dimension may be referred to as the distal edge.

Ions from the ion beam 1 that are extracted through the extraction aperture 115 may strike the suppression electrode 200, typically proximate the optical edge. Additionally, ions from the ion beam 1 may also strike the ground electrode 210, typically proximate the optical edge.

As the optical edge of the suppression electrode 200 heats due the bombardment of ions, the length of the suppression electrode 200 may increase. This increase in length may be determined based on the coefficient of thermal expansion of the material used to create the suppression electrode 200. However, the increase in length may not be equal over the entirety of the suppression electrode 200. For example, due to the thermal resistivity of the material used to construct the suppression electrode 200, the distal edge of the suppression electrode 200, which is not being directly struck with ions, may not be as hot as the optical edge of the suppression electrode 200. This causes the optical edge of the suppression electrode 200 to expand more than the distal edge, causing the suppression electrode 200 to warp or distort.

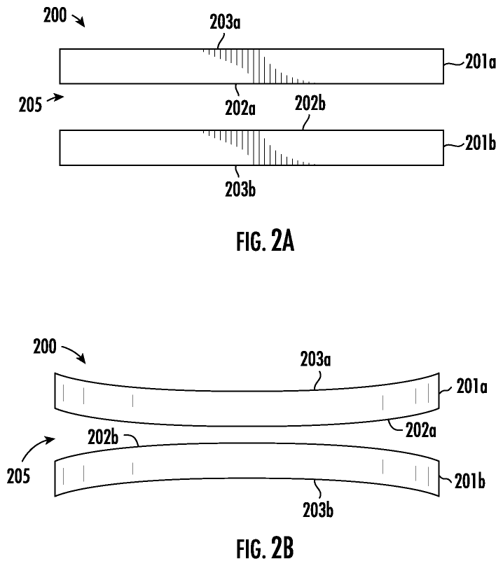

FIG. 2A shows a suppression electrode 200 which is made up of two components 201a, 201b. The space between the two components 201a, 201b defines the suppression aperture 205. Before the ion beam 1 is extracted, these two components 201a, 201b are not distorted, such that the optical edges 202a, 202b of the two components 201a, 201b, respectively, are parallel to one another.

As the ion beam 1 is extracted, ions strike the optical edges 202a, 202b of the components 201a, 201b, which causes these optical edges to expand. However, as described above, the distal edges 203a, 203b of the components 201a, 201b may not expand to the same extent due to the difference in temperature. Consequently, the suppression electrode 200 becomes distorted, as shown in FIG. 2B. This distortion is exaggerated for purposes of illustration. In this figure, the optical edges 202a, 202b have expanded causing each component 201a, 201b to warp. In certain embodiments, the middle portion of each optical edge 202a, 202b in the length dimension bows toward the other optical edge 202a, 202b. This causes the shape of the suppression aperture 205 to become irregular such that the suppression aperture 205 may be narrower in the middle portion than at the outer portions in the length dimension. Thus, the beam current of the ion beam 1 becomes non-uniform as a function of length, which may be problematic. Furthermore, as the length of the suppression electrode 200 increases, the distortion caused by thermal expansion may be exacerbated.

The extraction electrode 112 and the ground electrode 210 may be similarly distorted by the ion beam 1.

To compensate for this unwanted distortion, cooling channels 310 may be embedded in the suppression electrode 200. Cooling channels 310 may be likewise embedded in the ground electrode 210 or the extraction electrode 112. Further, in systems that employ more than two electrodes, the cooling channels 310 may be embedded in any or all of these electrodes.

Because the electrodes are disposed in the processing chamber, the choice of materials that may be used to create the embedded cooling channel may be limited. For example, traditional brazing techniques employ materials that are not suitable for the processing chamber. Consequently, traditional manufacturing techniques may be unacceptable.

However, newer additive manufacturing techniques may be useful. For example, in one embodiment, ultrasonic additive manufacturing (UAM) may be utilized. In this embodiment, a traditional electrode is manufactured. In some embodiments, a portion of the electrode may be machined to create a channel on the exposed surface of the electrode. UAM can then be used to successively apply thin layers of material to the electrode, effectively covering the channel to create an embedded channel. FIG. 3 shows one such embedded cooling channel 310 that may be created in an electrode 300 using this approach. Note that the material 320 above the cooling channel 310 may be added using UAM.

Alternatively, other additive manufacturing techniques such as direct melt laser sintering (DMLS), selective laser sintering (SLS) and Direct Energy Deposition (DED) may be used to create the electrode with the embedded cooling channel.

Thus, in this disclosure, the term “embedded cooling channel” refers to a cooling channel that is at least partially disposed in the body of the electrode. Thus, cooling channels that are brazed, soldered, swaged or otherwise affixed to the outer surface of the electrode are not considered embedded cooling channels.

The use of additive manufacturing also allows the embedded cooling channel to be lined with a more thermally conductive material. For example, as shown in FIG. 3, a liner 330 may be disposed around the embedded cooling channel 310. In certain embodiments, copper may be used to line the embedded cooling channel 310. Since the copper is completely contained within the electrode, there is no risk of contamination of the processing chamber.

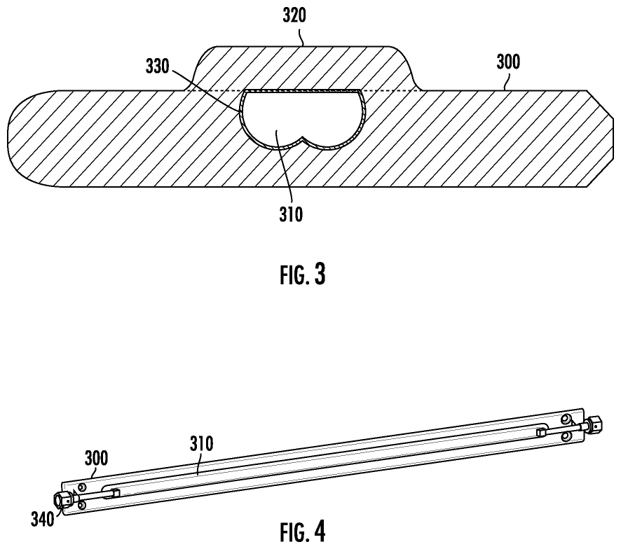

FIG. 4 shows a perspective view of the electrode 300 with the embedded cooling channel 310. In this figure, external connectors 340 have been attached so that the embedded cooling channel 310 may be in communication with a fluid.

In certain embodiments, the embedded cooling channel may be a single channel having a constant cross-section similar to that shown in FIG. 3. However, other embodiments are also possible. For example, the embedded cooling channel may be serpentine shaped. Further, FIG. 3 shows the embedded cooling channel 310 disposed near the center of the electrode in the width direction. However, in other embodiments, the embedded cooling channel 310 may be offset in the height direction. For example, the embedded cooling channel 310 may be disposed closer to the optical edge. Further, while FIG. 3 shows a single embedded cooling channel, it is understood that more than one embedded cooling channel may be disposed in the electrode. These multiple channels may be merged together within the electrode, or may be connected externally.

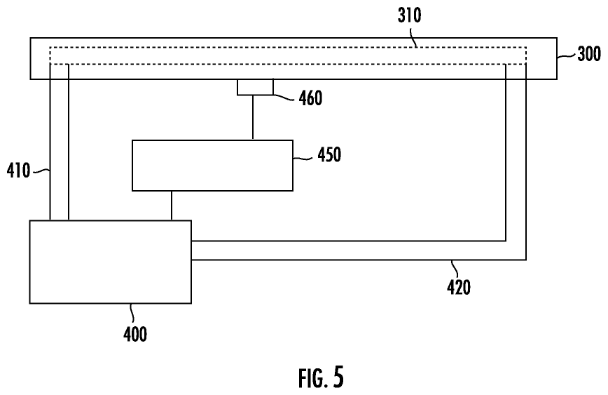

In certain embodiments, the embedded cooling channels 310 are in fluid communication with one or more fluid sources. The fluid sources may contain water or another fluid, including liquids or gasses. In one embodiment, shown in FIG. 5, the fluid source 400 may be a chiller. The embedded cooling channel 310 of the electrode 300 is connected to a chiller via two conduits 410, 420. In this way, the fluid is chilled so that the electrode 300 is maintained at ambient temperature or lower. For example, the fluid may be water, chilled to a temperature less than room temperature. In certain embodiments, a controller 450 may be utilized. The controller 450 may include a processing unit and a storage element. The storage element may be any suitable non-transitory memory device, such as semiconductor memory (i.e., RAM, ROM, EEPROM, FLASH RAM, DRAM, etc.), magnetic memory (i.e., disk drives), or optical memory (i.e., CD ROMs). The storage element may be used to contain the instructions, which when executed by the processing unit in the controller 450, allow the fluid source 400 to control the thermal distortion of the electrode 300. Specifically, the controller 450 may control the flow rate and/or temperature of the fluid so as to maintain the electrode 300 within a predetermined temperature range.

In some embodiments, a thermal sensor 460 may be disposed on or near the electrode 300 to measure the temperature of the electrode 300. In certain embodiments, the thermal sensors 460 are disposed near both the optical edge and the distal edge. In other embodiments, the thermal sensors 460 are only disposed near one of these two edges. These thermal sensors 460 may be thermocouples, resistance temperature detectors (RTDs) or other types of thermal sensors. In another embodiment, the thermal sensors 460 may not be disposed on the electrode 300. For example, the thermal sensor 460 may be an infrared camera, which may be disposed in a location such that the temperature of the electrode 300 may be measured remotely. The infrared camera may be used interchangeably with the RTDs or thermocouples in any of these embodiments.

Based on this information, the controller 450 may control the temperature and/or flow rate of the fluid in the chiller or other fluid source.

In other embodiments, the fluid source 400 may include a heater so as to maintain the fluid at a temperature that is above ambient temperature. For example, in certain embodiments, material from the RF ion source 100 may be less likely to be deposited on the electrode 300 if its temperature is elevated. Thus, although the channels are referred to as cooling channels, it is understood that they may be used to heat the electrode as well.

In other words, the controller 450 may control the temperature of the electrode 300 based on the species being ionized in the RF ion source 100 to minimize deposition of the electrode. The controller 450 may do this by controlling the temperature of the fluid from the fluid source flowing through the embedded cooling channel.

The present apparatus has many advantages.

First, the flow of fluid through the embedded cooling channels may help maintain the entirety of the electrodes at a uniform temperature. This reduces the likelihood of thermal distortion of the electrode, as shown in FIG. 2B.

Second, the ability to control the temperature of the electrode may be useful in reducing the rate of deposition on the electrodes. For example, certain species are more likely to deposit on the electrode if the electrode is at an elevated temperature. For these species, the electrode may be maintained at a lower temperature. Conversely, other species may be more likely to deposit on the electrode if the electrode is at a cooler temperature. For these species, the fluid may be heated to maintain the electrode at an elevated temperature.

Third, in some embodiments, the ion implantation system cannot be used until the electrodes reach their steady state temperature. By passing fluid at that temperature through the embedded cooling channels, the electrodes can reach that steady state temperature more quickly, allowing increased operational time.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. An apparatus for controlling thermal distortion of an electrode, comprising:
an ion source having a plurality of chamber walls defining an ion source chamber and having an extraction aperture; and
an electrode disposed outside the ion source chamber and having an aperture aligned with the extraction aperture, wherein the electrode has an embedded cooling channel.

2. The apparatus of claim 1, comprising a fluid source in communication with the embedded cooling channel to allow a flow of fluid through the electrode.

3. The apparatus of claim 2, wherein the fluid source comprises a chiller.

4. The apparatus of claim 2, wherein the fluid source comprises a heater.

5. The apparatus of claim 1, wherein the embedded cooling channel is lined with a thermally conductive material.

6. The apparatus of claim 5, wherein the thermally conductive material is copper.

7. The apparatus of claim 1, wherein the electrode comprises a suppression electrode.

8. The apparatus of claim 1, wherein the electrode comprises a ground electrode.

9. An apparatus for controlling thermal distortion and/or deposition of an electrode, comprising:
an ion source having a plurality of chamber walls defining an ion source chamber and having an extraction aperture;
an electrode disposed outside the ion source chamber and having an aperture aligned with the extraction aperture, wherein the electrode has an embedded cooling channel;
a fluid source in communication with the embedded cooling channel; and
a controller in communication with the fluid source to control a flow rate and/or temperature of a fluid flowing through the embedded cooling channel.

10. The apparatus of claim 9, wherein the controller maintains the electrode within a predetermined temperature range to control thermal distortion.

11. The apparatus of claim 10, comprising a thermal sensor, wherein the controller uses information from the electrode to maintain the predetermined temperature range.

12. The apparatus of claim 11, wherein the thermal sensor is disposed on the electrode.

13. The apparatus of claim 11, wherein the thermal sensor is not in direct contact with the electrode.

14. The apparatus of claim 9, wherein the fluid source comprises a chiller.

15. The apparatus of claim 9, wherein the fluid source comprises a heater.

16. The apparatus of claim 9, wherein the controller controls a temperature of a fluid flowing through the embedded cooling channel based on a species being ionized in the ion source to control deposition on the electrode.

17. An apparatus for controlling thermal distortion of an extraction electrode, comprising:
an ion source having a plurality of chamber walls and an extraction electrode defining an ion source chamber, wherein the extraction electrode has an extraction aperture; and
an electrode disposed outside the ion source chamber and having an aperture aligned with the extraction aperture, wherein the extraction electrode has an embedded cooling channel.

18. The apparatus of claim 17, comprising a fluid source in communication with the embedded cooling channel to allow a flow of fluid through the extraction electrode.

19. The apparatus of claim 18, wherein the fluid source comprises a chiller or a heater.

20. The apparatus of claim 17, wherein the embedded cooling channel is lined with a thermally conductive material.
